(19) United States
(12) Patent Application Publication
(10) Pub. No.: US 2024/0266446 A1
(43) Pub. Date: Aug. 8, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yuhki FUJINO, Kanazawa Ishikawa (JP); Tatsuya OHGURO, Kanazawa Ishikawa (JP)

(21) Appl. No.: 18/458,087

(22) Filed: Aug. 29, 2023

(30) Foreign Application Priority Data
Feb. 6, 2023 (JP) 2023-016241

(51) Int. Cl. H01L 29/94; H01L 29/06

(52) U.S. Cl. CPC H01L 29/945; H01L 29/0603

(57) ABSTRACT

A semiconductor device includes a semiconductor layer, an insulating film, a first conductive portion, and a second conductive portion. The first conductive portion is provided in the semiconductor layer. The insulating film is provided in the semiconductor layer. The insulating film is provided between the semiconductor layer and the first conductive portion. The second conductive portion is provided in the semiconductor layer. The second conductive portion is disposed such that the first conductive portion is located between the second conductive portion and the insulating film. The second conductive portion is electrically connected to the first conductive portion. The second conductive portion has residual stress with force components in directions opposite to directions of force components of residual stress of the first conductive portion.

### CROSS-REFERENCE TO RELATED APPLICATION(S)

This application is based upon and claims the benefit of priority from Japanese Patent Application No. 2023-016241, filed Feb. 6, 2023, the entire contents of which are incorporated herein by reference.

### FIELD

Embodiments described herein relate generally to a semiconductor device.

### BACKGROUND

A semiconductor device having capacitors formed in trenches of a semiconductor layer has been developed. The semiconductor device has an insulating film provided on the semiconductor layer in each trench, and a conductive portion is provided on the insulating film. Charges are stored between the semiconductor layer and the conductive portion. In such a semiconductor device, there is a fear of warpage due to residual stress of the conductive portion.

### DESCRIPTION OF THE DRAWINGS

FIGS. 1-2 are different schematic cross-sectional views of a semiconductor device according to an embodiment.

FIG. 3 is a schematic cross-sectional view illustrating a semiconductor device according to a reference example.

FIGS. 4A through 4C are schematic cross-sectional views illustrating semiconductor devices according to variations of the embodiment.

FIGS. 5-6 are different schematic cross-sectional views of another semiconductor device according to the embodiment.

FIGS. 7A through 7C are schematic cross-sectional views illustrating semiconductor devices according to variations of the embodiment.

FIG. 8 is a schematic perspective view illustrating a semiconductor device according to an embodiment.

FIG. 9 is a schematic cross-sectional view illustrating the semiconductor device according to the embodiment.

### DETAILED DESCRIPTION

Embodiments provide a semiconductor device whose warpage can be prevented.

In general, according to one embodiment, a semiconductor device includes a semiconductor layer, an insulating film, a first conductive portion, and a second conductive portion.

The first conductive portion is provided in the semiconductor layer. The insulating film is provided in the semiconductor layer. The insulating film is provided is provided between the semiconductor layer and the first conductive portion. The second conductive portion is provided in the semiconductor layer. The second conductive portion is disposed such that the first conductive portion is located between the second conductive portion and the insulating film. The second conductive portion is electrically connected to the first conductive portion. The second conductive portion has residual stress with force components in directions opposite to directions of force components of residual stress of the first conductive portion.

Embodiments of the present disclosure will now be described with reference to the drawings. The drawings are schematic or conceptual; thus, the dimensional ratio between the thickness and width of a component or element, size ratios between components or elements, etc. are not necessarily to scale. The same component or element may be depicted as having different sizes or dimensional ratios in different drawings. In the drawings and the description below, the same symbols are used for the same or similar components or elements, and a detailed description thereof will sometimes be omitted.

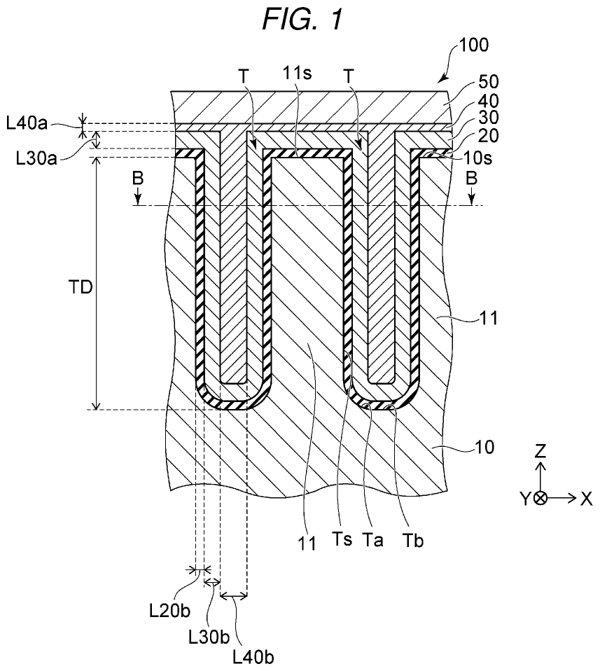

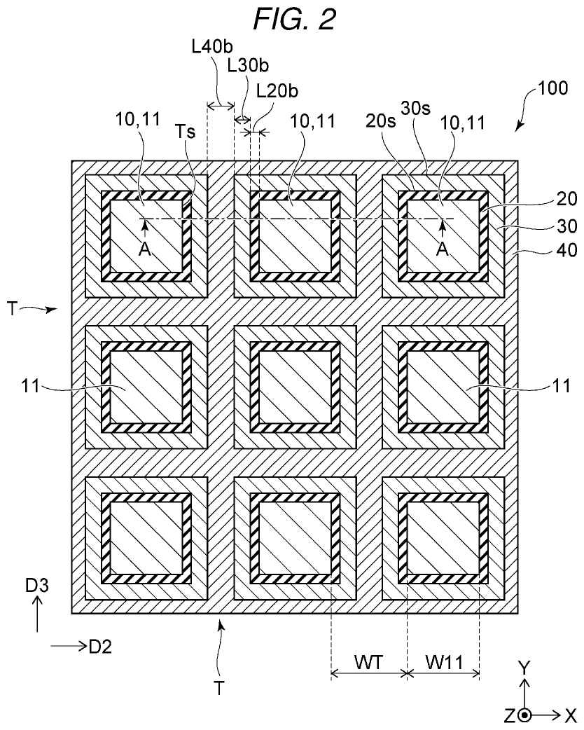

FIGS. 1 and 2 are schematic cross-sectional views illustrating a semiconductor device according to an embodiment. FIG. 1 corresponds to a cross-section along line A-A shown in FIG. 2. FIG. 2 corresponds to a cross-section along line B-B shown in FIG. 1.

As shown in FIG. 1, the semiconductor device 100 according to the embodiment includes a semiconductor layer 10, an insulating film 20, a first conductive portion 30, a second conductive portion 40, and a third conductive portion 50. The semiconductor device 100 is, for example, a silicon capacitor.

An XYZ Cartesian coordinate system is used in the following description. A direction from the semiconductor layer 10 toward the third conductive portion 50 is herein referred to as Z direction. Two directions which are perpendicular to the Z direction and perpendicular to each other are referred to as X direction and Y direction. For illustration purpose, a direction from the semiconductor layer 10 toward the third conductive portion 50 may be hereinafter referred to as “upward”, “above”, or the like, and the opposite direction as “downward”, “below”, or the like. Such directions are based on the relative positional relationship between the semiconductor layer 10 and the third conductive portion 50, and are not related to the direction of gravity.

The semiconductor layer 10 is, for example, a semiconductor substrate and has an upper surface 10s (e.g., the main surface of the semiconductor substrate). The Z direction corresponds to the direction perpendicular to the upper surface 10s of the semiconductor layer 10. The upper surface 10s extends along the X-Y plane.

Trenches T are provided in an upper portion of the semiconductor layer 10. Each trench T has a trench inner surface Ta including a trench bottom surface Tb, and trench side surfaces Ts extending upward from the trench bottom surface Tb.

In other words, projecting raised portions 11 (e.g., mesa portions) are provided in the upper portion of the semiconductor layer 10. Each raised portion 11 is located between adjacent trenches T in the X-Y plane. Each side surface of each raised portion 11 corresponds to the trench side surface Ts of an adjacent trench T, and an upper surface 11s of each raised portion 11 corresponds to the upper surface 10s of the semiconductor layer 10. In the illustrated example, the trench side surfaces Ts are substantially parallel to the Z direction; however, the trench side surfaces Ts may be inclined with respect to the Z direction.

The depth TD of each trench T (i.e., the Z-direction length from the upper surface 10s to the trench bottom surface Tb) is, for example, not less than 10 micrometers (μm) and not more than 100 μm.

The semiconductor layer 10 comprises, for example, silicon. A single crystal silicon substrate, for example, is used as the semiconductor layer 10. The semiconductor layer 10 is, for example, an n-type semiconductor doped with an n-type impurity such as phosphorus or arsenic. The concentration of the n-type impurity in the upper portion of the semiconductor layer 10, in which the trenches T are formed, may be higher than the concentration of the n-type impurity in the lower portion of the semiconductor layer 10. Alternatively, the semiconductor layer 10 may 10 may be a p-type semiconductor.

The insulating film 20 is superimposed on the semiconductor layer 10. The insulating film 20 has portions provided on the inner surfaces Ta of the trenches T. Thus, the insulating film 20 is partly provided along and in contact with the trench inner surfaces Ta.

More specifically, some portions of the insulating film 20 lie along and in contact with the trench side surfaces Ts. Other portions of the insulating film 20 lie along and in contact with the trench bottom surfaces Tb. Further, the insulating film 20 has portions which lie along and in contact with the upper surfaces 11s of the raised portions 11. Thus, the insulating film 20 is provided continuously such that it covers the trench inner surfaces Ta and the tops of the raised portions 11.

The insulating film 20 comprises, for example, at least one of silicon oxide (SiO₂), silicon nitride (SiN), and silicon oxynitride (SiON). The thickness of the insulating film 20 (the length L20b, along the direction perpendicular to the trench side surface Ts, of the insulating film 20 lying along the trench side surface Ts) is, for example, not less than 10 nm and not more than 300 nm.

The first conductive portion 30 is superimposed on the insulating film 20. The first conductive portion 30 has portions provided on the insulating film 20 in the trenches T. Thus, the first conductive portion 30 is partly located inside the insulating film 20 in the trenches T. Some portions of the first conductive portion 30 are provided along and in contact with the insulating film 20 in the trenches T. The first conductive portion 30 is insulated by the insulating film 20 from the semiconductor layer 10.

More specifically, the first conductive portion 30 is in contact with those portions of the insulating film 20 which lie along the trench side surfaces Ts. Further, the first conductive portion 30 is in contact with those portions of the insulating film 20 which lie along the trench bottom surfaces Tb. Furthermore, the first conductive portion 30 is in contact with those portions of the insulating film 20 which lie along the upper surfaces 11s of the raised portions 11. Thus, the first conductive portion 30 is provided continuously such that it covers those portions of the insulating film 20 which lie along the trench inner surfaces Ta and those portions of the insulating film 20 which lie along the upper surfaces 11s of the raised portions 11.

Polysilicon, for example, is used for the first conductive portion 30. The polysilicon is doped with an impurity such as an n-type impurity.

The second conductive portion 40 is superimposed on the first conductive portion 30. The second conductive portion 40 has portions provided on the first conductive portion 30 in the trenches T. Thus, the second conductive portion 40 is partly located inside the first conductive portion 30 in the trenches T. Some portions of the second conductive portion 40 are provided along and in contact with the first conductive portion 30 in the trenches T. The second conductive portion 40 is electrically connected to the first conductive portion 30. The second conductive portion 40 may be a metal film comprising a metal.

More specifically, the second conductive portion 40 is in contact with those portions of the first conductive portion 30 which lie on the insulating film 20 on the trench side surfaces Ts. Further, the second conductive portion 40 is in contact with those portions of the first conductive portion 30 which lie on the insulating film 20 on the trench bottom surfaces Tb. Furthermore, the second conductive portion 40 is in contact with those portions of the first conductive portion 30 which lie on the insulating film 20 on the upper surfaces 11s of the raised portions 11. Thus, the second conductive portion 40 is provided continuously such that it covers those portions of the first conductive portion 30 which lie on the trench inner surfaces Ta and those portions of the first conductive portion 30 which lie on the upper surfaces 11s of the raised portions 11. In the illustrated example, the space inside the first conductive portion 30 in each trench T is filled with the second conductive portion 40.

The second conductive portion 40 comprises a material having residual stress in a direction opposite to the direction of residual stress of the first conductive portion 30. For example, the first conductive portion 30 has residual stress that pulls and expands the semiconductor layer 10 in a direction along the X-Y plane. The first conductive portion 30 has, for example, residual stress that applies such a force to the semiconductor layer 10 as to warp the semiconductor layer 10 upward. On the other hand, the second conductive portion 40 has, for example, residual stress that shrinks the semiconductor layer 10 in a direction along the X-Y plane. The second conductive portion 40 has, for example, residual stress that applies such a force to the semiconductor layer 10 as to warp the semiconductor layer 10 downward. Residual stress, which means stress present in an object in the absence of any external load or force, is caused, for example, by a difference in lattice constant between films which are stacked on each other. Residual stress of the second conductive portion 40 includes force components in directions opposite to the directions of residual stress of the first conductive portion 30. Alternatively to the above, residual stress of the first conductive portion 30 may include force components in such directions as to warp the semiconductor layer 10 downward, and residual stress of the second conductive portion 40 may include force components in such directions as to warp the semiconductor layer 10 upward.

The thickness of the second conductive portion 40 is, for example, 0.2 to 5.0 times the thickness of the first conductive portion 30. The thickness of the second conductive portion 40 is, for example, the length L40a along the Z direction of the second conductive portion 40 lying above the upper surfaces 11s. In this case, the thickness of the first conductive portion 30 is the length L30a along the Z direction of the first conductive portion 30 lying above the upper surfaces 11s. Thus, the length L40a is, for example, 0.2 to 5.0 times the length L30a.

Alternatively, the thickness of the second conductive portion 40 may be, for example, the length L40b, along the direction perpendicular to the trench side surface Ts, of the second conductive portion 40 lying along the trench side surface Ts. In this case, the thickness of the first conductive portion 30 is the length L30b, along the direction perpendicular to the trench side surface Ts, of the first conductive portion 30 lying along the trench side surface Ts. Thus, the length L40b may be, for example, 0.2 to 5.0 times the length L30b.

The length L30a is, for example, not less than 100 nm and not more than 2000 nm. The length L30b is, for example, not less than 50 nm and not more than 2000 nm. The length L40a is, for example, not less than 20 nm and not more than 800 nm. The length L40b is, for example, not less than 40 nm and not more than 1600 nm.

The electrical resistivity (Ω·cm) of the second conductive portion 40 is lower than the electrical resistivity of the first conductive portion 30.

The second conductive portion 40 comprises, for example, at least one of titanium (Ti), titanium nitride (TiN), and tungsten (W). The second conductive portion 40 may have a stacked structure including a plurality of metal films. For example, the second conductive portion 40 has a stacked structure including a film comprising Ti, a film comprising TiN, and a film comprising W. The second conductive portion 40 may comprise, for example, a compound such as a silicide.

The third conductive portion 50 is superimposed on the second conductive portion 40. The third conductive portion 50 is in contact with the second conductive portion 40 at a position above the raised portions 11 and the trenches T, and is electrically connected to the second conductive portion 40. The third conductive portion 50 is not provided in the trenches T. The third conductive portion 50 comprises, for example, aluminum (Al). The electrical resistivity of the third conductive portion 50 is lower than the electrical resistivity of the first conductive portion 30. The electrical resistivity of the third conductive portion 50 is equal to or lower than the electrical resistivity of the second conductive portion 40.

As shown in FIG. 2, in the illustrated example, the trenches T are provided in a lattice pattern in the X-Y plane. Each of the columnar raised portions 11 is provided such that it is surrounded by trenches T. In the illustrated example, each raised portion 11 has a quadrilateral planar shape when viewed along the Z direction.

The raised portions 11 are arranged side-by-side in a second direction D2 and in a third direction D3. The second direction D2 is a direction perpendicular to the Z direction and, in the illustrated example, coincides with the X direction. The third direction D3 is a direction perpendicular to the Z direction and intersecting the X direction and, in the illustrated example, coincides with the Y direction. Some trenches T extend in a direction perpendicular to the second direction D2 between two raised portions 11 adjacent to each other in the second direction D2. Other trenches T extend in a direction perpendicular to the third direction D3 between two raised portions 11 adjacent to each other in the third direction D3.

The insulating film 20, the first conductive portion 30, the second conductive portion 40, and the third conductive portion 50 are formed continuously such that they cover the side surfaces and upper surfaces 11s of the raised portions 11. In the cross-section of FIG. 2 (the cross-section passing through the raised portions 11 and perpendicular to the Z direction), the insulating film 20 has a pattern of quadrilateral rings each surrounding the side surfaces of each columnar raised portion 11 (i.e., the trench side surfaces Ts). The first conductive portion 30 has a pattern of square rings each surrounding the side surfaces 20s of the insulating film 20. The second conductive portion 40 has a lattice pattern surrounding the side surfaces 30s of the first conductive portion 30.

The width W11 of each raised portion 11 (the length of each raised portion 11 along the second direction D2) is, for example, not less than 300 nm and not more than 2000 nm. The width WT of each trench T (the distance between two raised portions 11 adjacent to each other in the second direction D2) is, for example, not less than 300 nm and not more than 4000 nm. In the illustrated example, the trenches T extend with a substantially constant width WT in the X-Y plane. The width W11 may be larger or smaller than the width WT.

The first conductive portion 30 is electrically connected to the second conductive portion 40 and the third conductive portion 50. On the other hand, the first conductive portion 30 is insulated by the insulating film 20 from the semiconductor layer 10. Accordingly, the semiconductor device 100 functions as a semiconductor device which stores charges between the first conductive portion 30 and the semiconductor layer 10. For example, when a voltage is applied between an electrode electrically connected to the third conductive portion 50 and an electrode electrically connected to the semiconductor layer 10, charges are stored between the first conductive portion 30 and the semiconductor layer 10.

The semiconductor device 100 according to this embodiment is a semiconductor device to be connected to a power semiconductor device such as an IGBT (Insulated Gate Bipolar Transistor). For example, the semiconductor device 100 is used in a snubber circuit and connected in parallel with an IGBT. For example, one electrode of the semiconductor device 100 is electrically connected to an emitter of the IGBT, and the other electrode is electrically connected to a collector of the IGBT.

The effect of this embodiment will now be described with reference to a reference example.

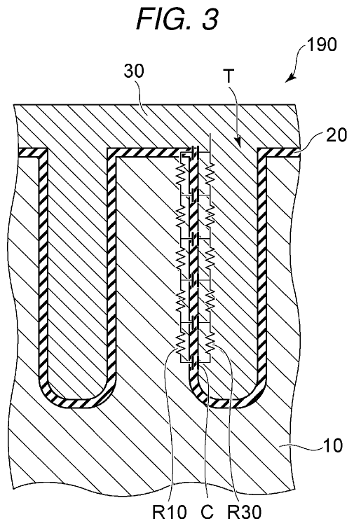

FIG. 3 is a schematic cross-sectional view illustrating a semiconductor device according to a reference example. In the semiconductor device 190 of the reference example shown in FIG. 3, unlike the semiconductor device 100, the second conductive portion 40 and the third conductive portion 50 are not provided, and the first conductive portion 30 is thicker than that of the semiconductor device 100. In the semiconductor device 190, the trenches T are filled with the first conductive portion 30. When the first conductive portion 30 is formed thick on the insulating film 20 during manufacture of the semiconductor device 190, the residual stress of the first conductive portion 30 can cause warpage of the semiconductor substrate (wafer).

A capacitor to be connected to a power semiconductor device, for example, is required to have a large electric capacitance. Therefore, it is conceivable to increase the electric capacitance per unit effective area by deepening the trenches. However, as the trenches become deeper, the first conductive portion 30 becomes thicker; the residual stress of the first conductive portion 30 is more likely to cause warpage. Further, as shown in FIG. 3, the electrical resistance R10 of the semiconductor layer 10 and the electrical resistance R30 of the first conductive portion 30 are connected to the electric capacitance C formed in the trench T. As the trench T becomes deeper, such electrical resistances increase, which may affect the performance, e.g. in the frequency characteristics, of the capacitor. For example, when a semiconductor device with a large resistance component is used to process a high-frequency signal, a signal delay can occur.

In the semiconductor device 100 according to this embodiment, the depth TD of the trenches T is not less than 10 μm. This enables a large electric capacitance, thus making it possible to provide, for example, a capacitor to be connected to a power semiconductor device. On the other hand, since the trenches T are deeper than 10 μm, there is the above-described fear of warpage of the wafer and an increase in the electrical resistance. However, in the semiconductor device 100, the second conductive portion 40 has residual stress in directions opposite to the direction of the residual stress of the first conductive portion 30. As a result, at least part of the residual stress of the first conductive portion 30 is canceled by at least part of the residual stress of the second conductive portion 40. This can reduce or prevent warpage of the wafer. Further, the provision of the second conductive portion 40 having a low electrical resistivity can reduce the resistance component connected to the electric capacitance. This makes it possible to prevent the occurrence of a signal delay.

As described above, the thickness of the second conductive portion 40 is, for example, 0.2 to 5.0 times the thickness of the first conductive portion 30. This can avoid the second conductive portion 40 being too thin or too thick relative to the first conductive portion 30, and can facilitate residual stress cancelation.

For example, the thickness of the second conductive portion 40 may be larger than the thickness of the first conductive portion 30. By making the second conductive portion 40 relatively thick, the resistance component connected to the electric capacitance can be reduced. However, the second conductive portion 40 may be thinner than the first conductive portion 30.

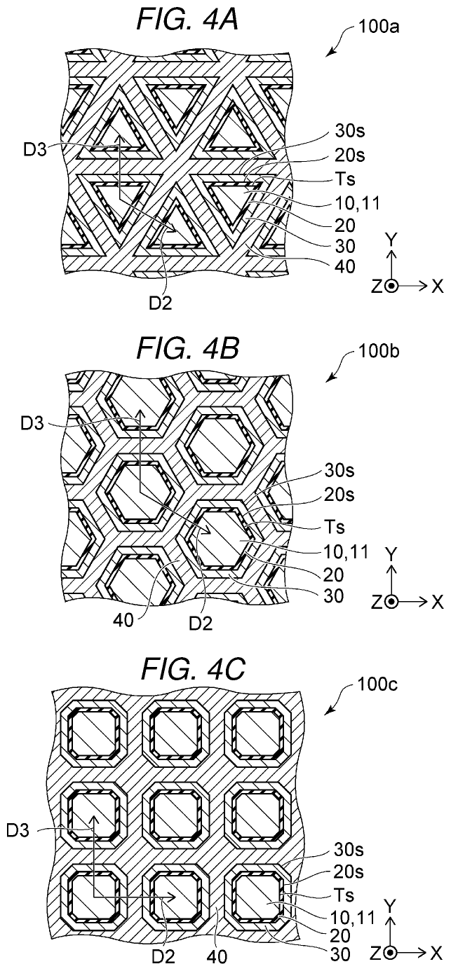

FIGS. 4A through 4C are schematic cross-sectional views illustrating semiconductor devices according to variations of this embodiment. As with FIG. 2, FIGS. 4A through 4C show cross-sections in the X-Y plane. The semiconductor devices 100a to 100c shown in FIGS. 4A through 4C each differ from the semiconductor device 100 in the planar shape of the raised portions 11.

In the semiconductor device 100a shown in FIG. 4A, the raised portions 11 each have a triangular shape when viewed in the Z direction. In the semiconductor device 100b shown in FIG. 4B, the raised portions 11 each have a hexagonal shape when viewed in the Z direction.

In the semiconductor device 100c shown in FIG. 4C, the raised portions 11 each have an octagonal shape when viewed in the Z direction.

Thus, the planar shape of the raised portions 11 can be a polygonal shape (e.g., a regular polygonal shape). For example, the planar shape of the raised portions 11 may be a square shape in FIG. 2, an equilateral triangular shape in FIG. 4A, and a regular hexagonal shape in FIG. 4B. In FIG. 4C, the planar shape of the raised portions 11 is a square shape with the four corners cut away linearly. The polygonal shape is not limited to a polygonal shape in a strict sense, and may be, for example, a polygonal shape with rounded corners.

As shown in FIGS. 4A through 4C, the insulating film 20 surrounds the peripheral side surfaces (trench side surfaces Ts) of each raised portion 11. The first conductive portion 30 surrounds the outer peripheral side surfaces 20s of the insulating film 20. The second conductive portion 40 surrounds the outer peripheral side surfaces 30s of the first conductive portion 30. By providing the insulating film 20, the first conductive portion 30, and the second conductive portion 40 such that they surround the polygonal columnar raised portions 11, the capacitance of the semiconductor device can be increased.

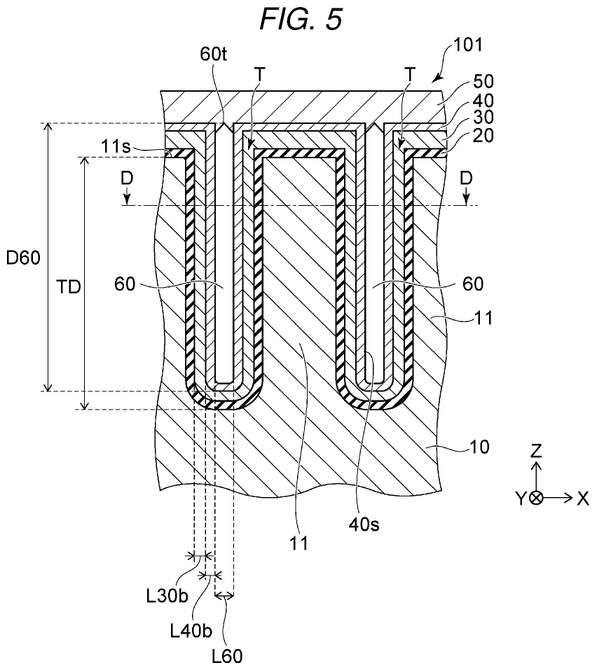

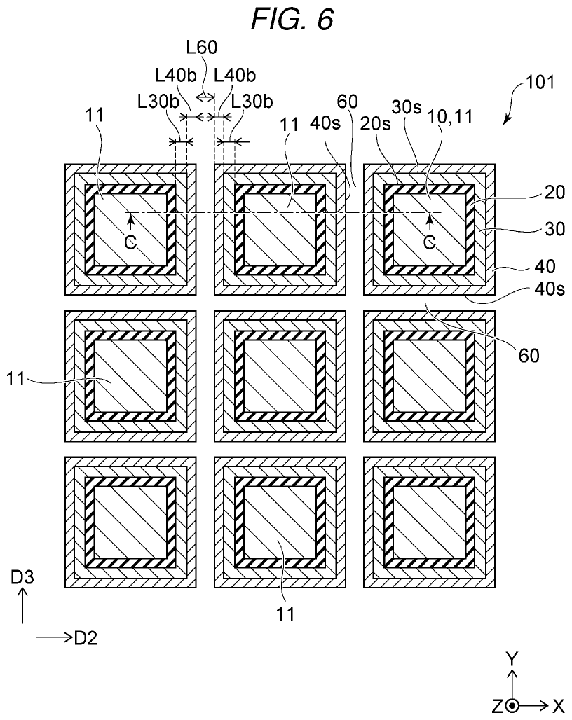

FIGS. 5 and 6 are schematic cross-sectional views illustrating another semiconductor device according to this embodiment. FIG. 5 shows a cross-section along line C-C shown in FIG. 6. FIG. 6 corresponds to a cross-section along line D-D shown in FIG. 5.

As shown in FIG. 5, the semiconductor device 101 according to this embodiment differs from the semiconductor device 100 in the provision of a cavity 60. The cavity 60 is formed inside the second conductive portion 40 in the trenches T.

The cavity 60 is surrounded by the second conductive portion 40 and the third conductive portion 50. Thus, the lower end and the sides of the cavity 60 are defined by the second conductive portion 40. The upper end of the cavity 60 is defined by the third conductive portion 50.

In the cross-section of FIG. 6 (the cross-section passing through the raised portions 11 and perpendicular to the Z direction), the second conductive portion 40 has a pattern of square rings each surrounding the outer peripheral side surfaces 30s of the first conductive portion 30. In the X-Y plane, the cavity 60 has a lattice pattern surrounding the outer peripheral side surfaces 40s of the second conductive portion 40.

The cavity 60 can buffer the residual stress of the semiconductor layer 10, the first conductive portion 30 or the second conductive portion 40. For example, even when the width of a raised portion 11 changes due to the residual stress of the first conductive portion 30 or the second conductive portion 40, the change in the width of the raised portion 11 can be absorbed by the cavity 60. The cavity 60 makes it possible to more effectively reduce or prevent warpage of the wafer as a whole.

As shown in FIG. 5, the length L60 is longer than the length L40b, and is longer than the length L30b. In other words, the width (length L60) of the cavity 60 is larger than the thickness of the second conductive portion 40, and is larger than the thickness of the first conductive portion 30. However, the length L60 may be shorter than the length L40b, and may be shorter than the length L30b. The length L60 refers to the length of a part of the cavity 60 along a direction perpendicular to the direction (e.g., the third direction D3) in which the part of the cavity 60 extends in the X-Y plane. The length L60 is, for example, not less than 50 nm and not more than 1000 nm.

As shown in FIG. 5, the length D60 of the cavity 60 along the Z direction may be equal to the depth TD of the trenches T. The length D60 is, for example, 0.1 to 1.1 times the depth TD. The length D60 is, for example, not less than 0.5 μm and not more than 110 μm. The upper end 60t of the cavity 60 is located, for example, above the upper end of the semiconductor layer 10. The upper end 60t of the cavity 60 may be disposed only above those portions of the insulating film 20 or the first conductive portion 30 which lie above the raised portions 11. The provision of such a long cavity 60 enables it to buffer the residual stress more securely.

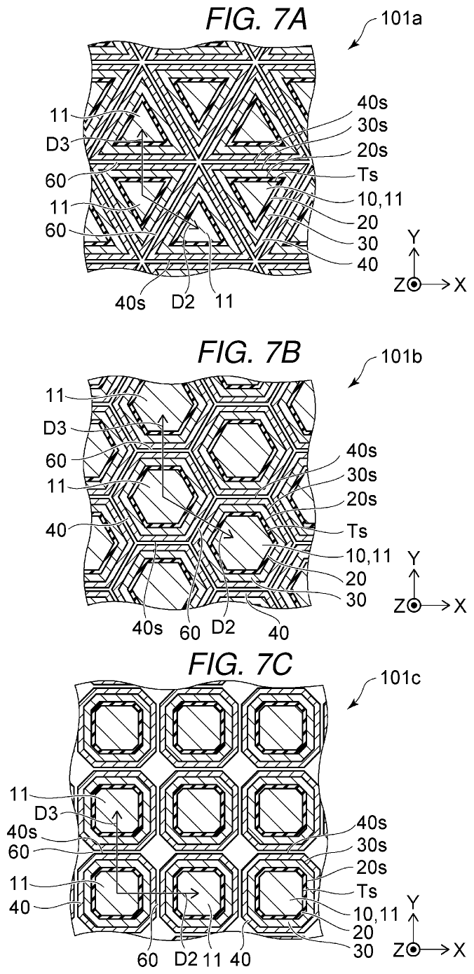

FIGS. 7A through 7C are schematic cross-sectional views illustrating semiconductor devices according to variations of this embodiment. As with FIG. 6, FIGS. 7A through 7C show cross-sections in the X-Y plane. The semiconductor devices 101a to 101c shown in FIGS. 7A through 7C each differ from the semiconductor device 101 in the planar shape of the raised portions 11.

In the semiconductor device 101a shown in FIG. 7A, the raised portions 11 each have a triangular shape when viewed in the Z direction. In the semiconductor device 101b shown in FIG. 7B, the raised portions 11 each have a hexagonal shape when viewed in the Z direction. In the semiconductor device 101c shown in FIG. 7C, the raised portions 11 each have an octagonal shape when viewed in the Z direction.

Also in the illustrated examples, in the X-Y plane, the cavity 60 has a lattice pattern surrounding the outer peripheral side surfaces 40s of the second conductive portion 40. For example, some portions of the cavity 60 extend in a direction perpendicular to the second direction D2 between two raised portions 11 adjacent to each other in the second direction D2. Other portions of the cavity 60 extend in a direction perpendicular to the third direction D3 between two raised portions 11 adjacent to each other in the third direction D3. Each of the portions of the cavity 60, extending in a direction perpendicular to the second direction D2, and each of the portions of the cavity 60, extending in a direction perpendicular to the third direction D3 intersect with and are connected to each other. Thus, the cavity 60 extends between the raised portions 11. Since the cavity 60 extends in multiple directions in the X-Y plane, the cavity 60 can buffer the residual stress in multiple directions. For example, the cavity 60 can distribute the residual stress in multiple directions.

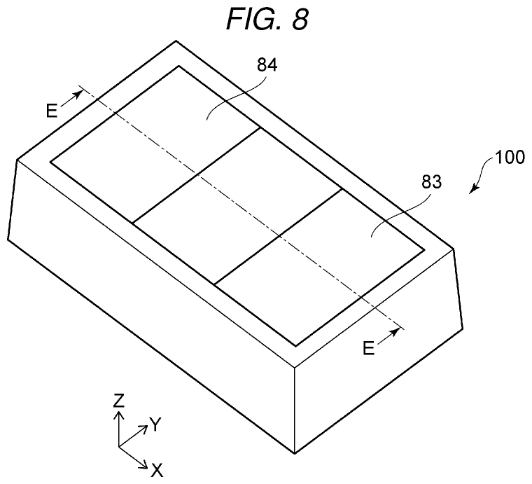

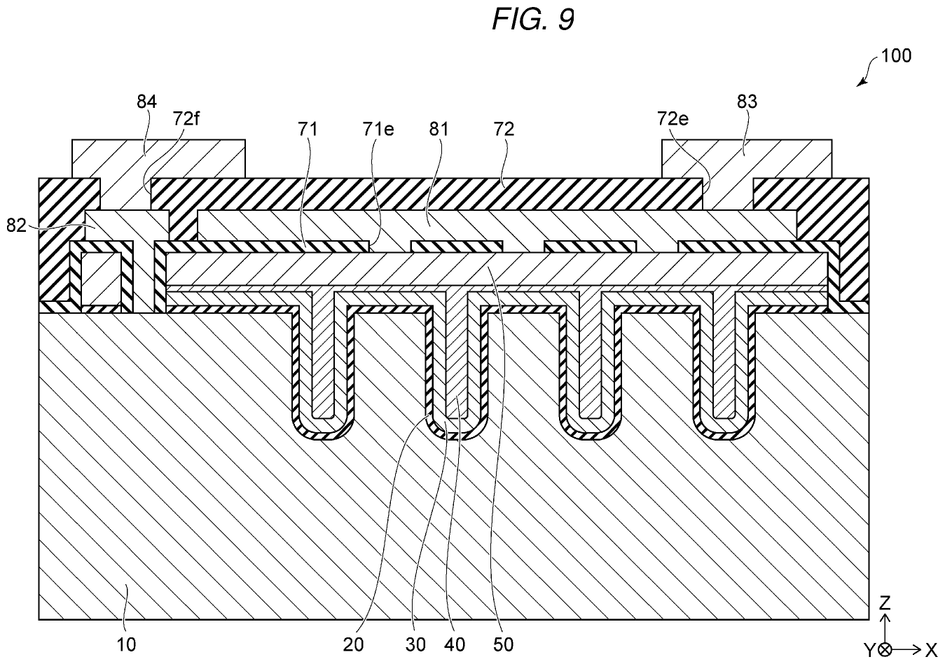

FIG. 8 is a schematic perspective view illustrating a semiconductor device according to an embodiment. FIG. 9 is a schematic cross-sectional view illustrating the semiconductor device according to the embodiment. FIG. 9 shows a cross-section along line E-E of FIG. 8.

For example, as shown in FIG. 9, an insulating film 71 is provided on the third conductive portion 50. A conductive portion 81 is provided on the insulating film 71. The conductive portion 81 is electrically connected to the third conductive portion 50 through openings 71e provided in the insulating film 71. An insulating film 72 and a first electrode pad 83 are provided on the conductive portion 81. The first electrode pad 83 is electrically connected to the conductive portion 81 through an opening 72e provided in the insulating film 72.

A conductive portion 82 is provided on and electrically connected to the semiconductor layer 10. The conductive portion 82 is disposed side-by-side with the conductive portion 81 in the X direction, and is insulated from the conductive portion 81. A second electrode pad 84 is provided on the conductive portion 82. The second electrode pad 84 is electrically connected to the conductive portion 82 through an opening 72f provided in the insulating film 72. The second electrode pad 84 is disposed side-by-side with the first electrode pad 83 in a direction (e.g., the X direction) in the X-Y plane. The insulating film 72 is provided between the second electrode pad 84 and the first electrode pad 83 to insulate the second electrode pad 84 from the first electrode pad 83.

With the above-described construction, the first electrode pad 83 is electrically connected to the first conductive portion 30 and insulated from the semiconductor layer 10. The second electrode pad 84 is electrically connected to the semiconductor layer 10 and insulated from the first conductive portion 30. By applying a voltage between the first electrode pad 83 and the second electrode pad 84, charges are stored between the first conductive portion 30 and the semiconductor layer 10.

According to the embodiments, it is possible to provide a semiconductor device whose warpage can be prevented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor layer;
a first conductive portion provided in the semiconductor layer;
an insulating film provided in the semiconductor layer and disposed between the semiconductor layer and the first conductive portion; and
a second conductive portion provided in the semiconductor layer, disposed such that the first conductive portion is located between the second conductive portion and the insulating film, and electrically connected to the first conductive portion,
wherein the second conductive portion has residual stress with force components in directions opposite to directions of force components of residual stress of the first conductive portion.

2. The semiconductor device according to claim 1, wherein a cavity is formed inside the second conductive portion.

3. The semiconductor device according to claim 2, wherein the upper end of the cavity is located above the upper end of the semiconductor layer.

4. The semiconductor device according to claim 1, wherein the thickness of the second conductive portion is 0.2 to 5.0 times the thickness of the first conductive portion.

5. The semiconductor device according to claim 1, wherein
the semiconductor layer includes raised portions projecting in a first direction, and
the insulating film surrounds the side surfaces of the raised portions, the first conductive portion surrounds the side surfaces of the insulating film, and the second conductive portion surrounds the side surfaces of the first conductive portion.

6. The semiconductor device according to claim 5, wherein in a plane perpendicular to the first direction, the raised portions each have a triangular shape, a quadrilateral shape, a hexagonal shape, or an octagonal shape.

7. The semiconductor device according to claim 1, wherein
the semiconductor layer includes a plurality of raised portions projecting in a first direction, and
the raised portions are arranged side-by-side in a second direction perpendicular to the first direction and in a third direction perpendicular to the first direction and intersecting the second direction.

8. The semiconductor device according to claim 1, wherein
the semiconductor layer includes a plurality of raised portions projecting in a first direction, and arranged side-by-side in a second direction perpendicular to the first direction and in a third direction perpendicular to the first direction and intersecting the second direction, and
cavities are formed inside the second conductive portion and extend between the raised portions.

9. The semiconductor device according to claim 1, wherein an electrical resistivity of the second conductive portion is lower than an electrical resistivity of the first conductive portion.

10. The semiconductor device according to claim 1, wherein the first conductive portion comprises polysilicon, and the second conductive portion comprises a metallic conductive portion.

11. The semiconductor device according to claim 10, wherein the second conductive portion has a stacked structure comprising a film comprising titanium, a film comprising titanium nitride, and a film comprising tungsten.

12. A semiconductor device comprising:
a semiconductor layer including a plurality of raised portions arranged in a lattice pattern;
an insulating film disposed on upper and sidewall potions of the raised portions;
a first conductive portion disposed on the insulating film; and
a second conductive portion disposed on the first conductive portion, wherein
the insulating film is between the semiconductor layer and the first conductive portion and the first conductive portion is between the insulating film and the second conductive portion, and
the first conductive portion has residual stress with first force components and the second conductive portion has residual stress with second force components, and directions of the first force components are opposite to directions of the second force components.

13. The semiconductor device according to claim 12, wherein the first force components cause warping of the semiconductor device in a first direction and the second force components cause warping of the semiconductor device in a second direction that is opposite to the first direction.

14. The semiconductor device according to claim 12, wherein the thickness of the second conductive portion is 0.2 to 5.0 times the thickness of the first conductive portion.

15. The semiconductor device according to claim 12, wherein the raised portions each have a triangular shape, a quadrilateral shape, a hexagonal shape, or an octagonal shape.

16. The semiconductor device according to claim 12, wherein cavities are formed inside the second conductive portion and extend between the raised portions.

17. The semiconductor device according to claim 12, wherein an electrical resistivity of the second conductive portion is lower than an electrical resistivity of the first conductive portion.

18. The semiconductor device according to claim 12, wherein the first conductive portion comprises polysilicon, and the second conductive portion comprises a metallic conductive portion.

19. The semiconductor device according to claim 18, wherein the second conductive portion has a stacked structure comprising a film comprising titanium, a film comprising titanium nitride, and a film comprising tungsten.

20. The semiconductor device according to claim 18, wherein an upper surface of the second conductive portion is planar and a planar conductive layer is disposed on the upper surface of the second conductive portion.
